(19) United States
(12) Patent Application Publication
(10) Pub. No.: US 2012/0021561 A1
(43) Pub. Date: Jan. 26, 2012

(54) PLASMA PROCESSING APPARATUS AND METHOD FOR MANUFACTURING SOLAR CELL USING SAME

(75) Inventor: Akira Terakawa, Osaka (JP)

(73) Assignee: Sanyo Electric Co. Ltd., Moriguchi-shi, Osaka (JP)

(21) Appl. No.: 13/260,601

(22) PCT Filed: Mar. 24, 2010
(86) PCT No.: PCT/JP2010/055022

§ 371 Date: Sep. 27, 2011

(30) Foreign Application Priority Data
Mar. 31, 2009 (JP) 2009-084788

(51) Int. Cl. H01L 31/18; C23C 16/448

(52) U.S. Cl. 438/98; 118/723 R; 257/E31.124

(57) ABSTRACT

A method of manufacturing a solar cell in which qualities and thicknesses of formed films are uniformed is obtained. This method of manufacturing a solar cell includes steps of forming a substrate-side electrode (11) on a substrate (10), forming at least part of a photoelectric conversion unit (12, 13) on the substrate-side electrode by supplying source gas from projecting portions of a plasma processing apparatus (1) including a first electrode (4) having the projecting portions (4b, 24a, 24b, 24c, 24d), made of a conductive porous material, provided to cover gas supply ports (4a), and forming a rear-side electrode (14) on the photoelectric conversion unit.

### TECHNICAL FIELD

The present invention relates to a plasma processing apparatus including electrodes having projecting portions and a method for manufacturing a solar cell by employing the same.

### BACKGROUND ART

A plasma processing apparatus including an electrode having projecting portions and a method of manufacturing a solar cell by employing the same are known in general.

In Japanese Patent Laying-Open No. 2006-237490, a plasma processing apparatus including a first electrode having projecting portions provided with single through-holes supplying source gas and a second electrode arranged to be opposed to the first electrode and a method of manufacturing a solar cell by employing the same are disclosed. The plasma processing apparatus is so formed that source gas is supplied through the through-holes of the projecting portions of the first electrode. The projecting portions are formed to supply the source gas in a direction directed from openings of the through holes on forward end portions of the projecting portions toward the second electrode. This plasma processing apparatus forms films by decomposing the source gas with plasma generated between the first electrode and the second electrode.

### PRIOR ART

### Patent Document

Patent Document 1: Japanese Patent Laying-Open No. 2006-237490

### SUMMARY OF THE INVENTION

### Problem to be Solved by the Invention

In the plasma processing apparatus described in Japanese Patent Laying-Open No. 2006-237490, however, the source gas is supplied in the direction directed from the openings of the through-holes on the forward end portions of the projecting portions toward the second electrode while the source gas cannot be sufficiently supplied between the adjacent projecting portions, and hence there is such a problem that qualities and thicknesses of films formed around the forward end portions of the projecting portions and films formed between the adjacent projecting portions are nonuniform.

The present invention has been proposed in order to solve the aforementioned problem, and aims at providing a plasma processing apparatus in which qualities and thicknesses of formed films are uniformed and a method of manufacturing a solar cell by employing the same.

### Means for Solving the Problem

A method of manufacturing a solar cell according to the present invention includes the steps of forming a substrate-side electrode on a substrate, forming at least part of a photoelectric conversion unit on the substrate-side electrode by supplying source gas from projecting portions of a plasma processing apparatus including a first electrode having the projecting portions, made of a conductive porous material, provided to cover gas supply ports, and forming a rear-side electrode on the photoelectric conversion unit.

A plasma processing apparatus according to the present invention includes a first electrode arranged in a processing chamber, a second electrode, opposed to the first electrode, capable of holding a substrate, and a gas supply source supplying gas into the processing chamber, while the first electrode has a shower plate formed by a conductive substrate having gas supply ports and projecting portions, made of a conductive porous material, provided on a surface of the shower plate opposed to the second electrode to cover the gas supply ports, and is formed to supply source gas from the projecting portions.

### Effects of the Invention

In the method of manufacturing a solar cell according to the present invention, film qualities and film thicknesses can be inhibited from becoming nonuniform even if a film formation rate is increased, whereby desired excellent films can be formed. Thus, the film formation rate can be increased while preventing reduction of output characteristics of the solar cell.

According to the inventive plasma processing apparatus, qualities and thicknesses of films formed around forward end portions of the projecting portions and films formed between a plurality of projecting portions can be inhibited from becoming nonuniform.

### BRIEF DESCRIPTION OF THE DRAWINGS

FIG. 1 A schematic diagram showing a plasma processing apparatus according to an embodiment of the present invention.

FIG. 2 An enlarged sectional view of an upper electrode of the plasma processing apparatus according to the embodiment of the present invention.

FIG. 3 A plan view of the upper electrode of the plasma processing apparatus according to the embodiment of the present invention as viewed from below.

FIG. 4 A schematic diagram showing a plasma processing apparatus according to comparative example.

FIG. 5 An enlarged sectional view around a lower electrode in the plasma processing apparatus according to comparative example.

FIG. 6 An enlarged sectional view of an upper electrode of a plasma processing apparatus according to a first modification of the embodiment of the present invention.

FIG. 7 An enlarged sectional view of an upper electrode of a plasma processing apparatus according to a second modification of the embodiment of the present invention.

FIG. 8 An enlarged sectional view of a solar cell according to the embodiment of the present invention.

### MODES FOR CARRYING OUT THE INVENTION

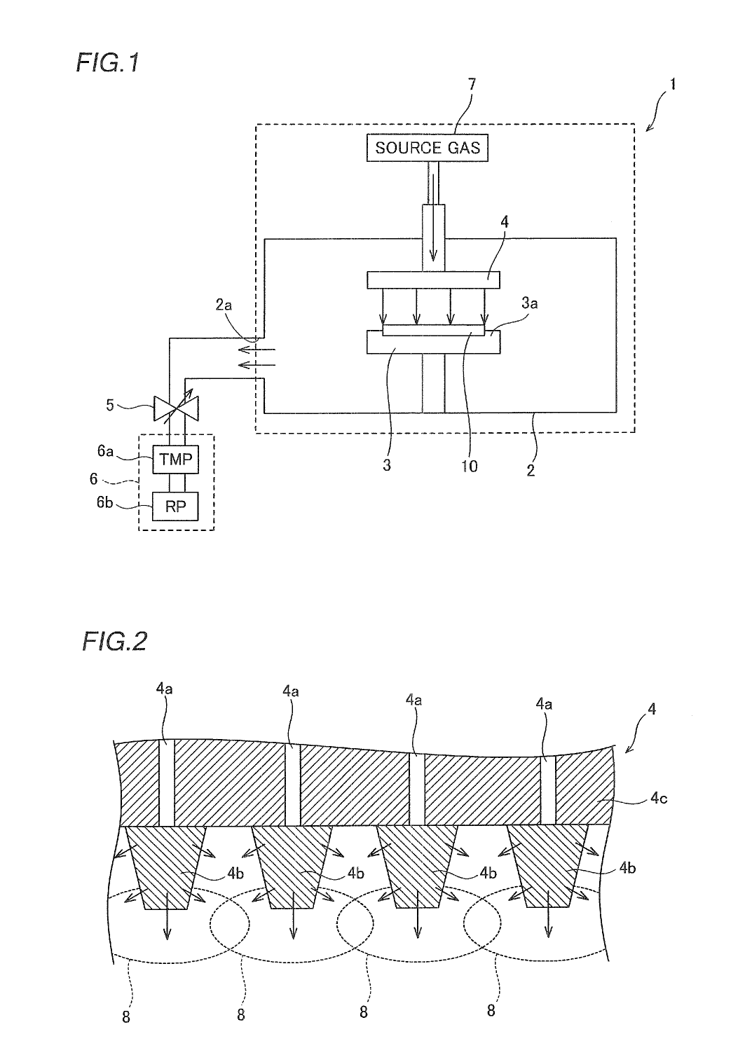

First, the structure of a plasma processing apparatus 1 according to an embodiment of the present invention is described with reference to FIGS. 1 to 3.

As shown in FIG. 1, an upper electrode 4 and a lower electrode 3 having parallel structures are set in a vacuum chamber 2 of the plasma processing 1 to be opposed to each other. The vacuum chamber 2, the upper electrode 4 and the lower electrode 3 are examples of the “processing chamber”, the “first electrode” and the “second electrode” in the present invention respectively.

The vacuum chamber 2 has an exhaust port 2a on a side portion, and the exhaust port 2a is connected to an evacuation system 6 through an evacuation flow regulating valve 5. According to this embodiment, the evacuation system 6 is constituted of a turbo molecular pump (TMP) 6a and an oil-sealed rotary vacuum pump (RP) 6b.

In the lower electrode 3, a substrate holding portion 3a capable of holding a substrate 10 is formed on a side opposed to the upper electrode 4. This lower electrode 3 includes an unshown heating/cooling mechanism portion for keeping the substrate 10 at a prescribed temperature. The surfaces of the upper electrode 4 and the lower electrode 3 on the sides opposed to each other have areas of about 1500 mm by about 1500 mm. The substrate 10 has an area of about 1400 mm by about 1100 mm.

As shown in FIG. 2, the upper electrode 4 includes projecting portions 4b and a shower plate 4c. The shower plate 4c is provided with gas supply ports 4a, and these gas supply ports 4a are connected to a source gas supply source 7.

The shower plate 4c is constituted of an Al (aluminum) plate. This shower plate 4c may simply be a conductive member, and Cu (copper), SUS (stainless steel) or the like may be employed, in place of Al employed in the first embodiment. The gas supply ports 4a are so provided that the distance between adjacent gas supply ports 4a is about 10 mm.

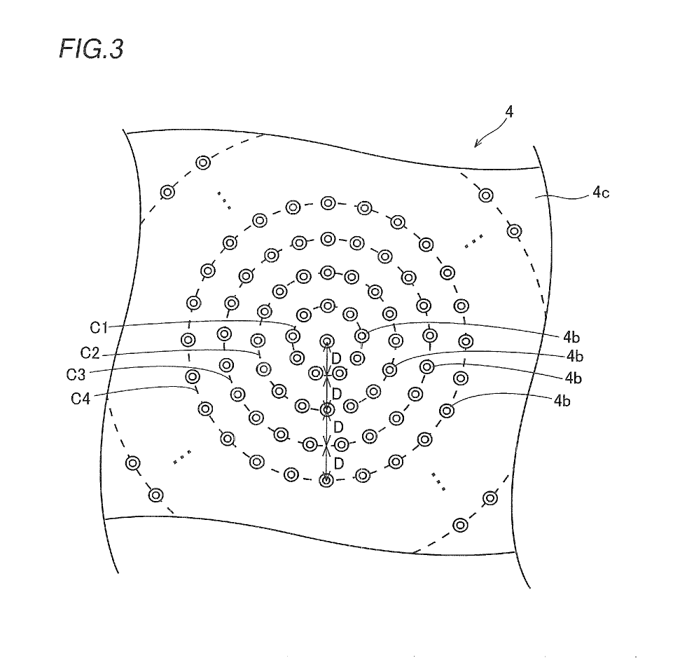

A plurality of projecting portions 4b, made of porous carbon, covering the gas supply ports 4a are provided on a surface of the shower plate 4c opposed to the lower electrode 3. As shown in FIG. 3, the plurality of projecting portions 4b are concentrically provided over the whole surface of the upper electrode 4 (shower plate 4c). The upper electrode 4 is so formed that distances D between a plurality of concentric circles C1, 2, C3, C4 . . . on which the projecting portions 4b are arranged are equal to each other between the concentric circles. It is assumed that the material employed for these projecting portions 4b must be a conductive porous material, whose gas permeability is excellent in addition to conductivity as an electrode, including pores capable of diffusing source gas in a prescribed range. More specifically, porosity of the conductive porous material is preferably set to at least 30% and not more than 70%. This porosity is defined by a volume content of pores which are small cavities contained in a lumped object. The projecting portions 4b made of the conductive porous material are formed to isotropically supply the source gas from the projecting portions 4b, as shown in FIG. 2. More specifically, the projecting portions 4b are formed to supply the source gas in a direction directed from forward end portions of the projecting portions 4b toward the lower electrode 3 an a direction directed from sidewall portions toward adjacent projecting portions 4b.

The projecting portions 4b have a height of about 3 mm, and are so formed that the sectional area (width in a direction along the surface of the shower plate 4c) is reduced from base portions toward the forward end portions. The forward end portions of these projecting portions 4b are formed to be positioned on straight lines extending in a perforation direction (direction where the gas supply ports 4a extend from the gas supply ports 4a) of the gas supply ports 4a provided on the shower plate 4c. The projecting portions 4b are so arranged that plasma generation regions 8 overlap with each other between adjacent projecting portions 4b. The projecting portions 4a are formed to isotropically generate plasma.

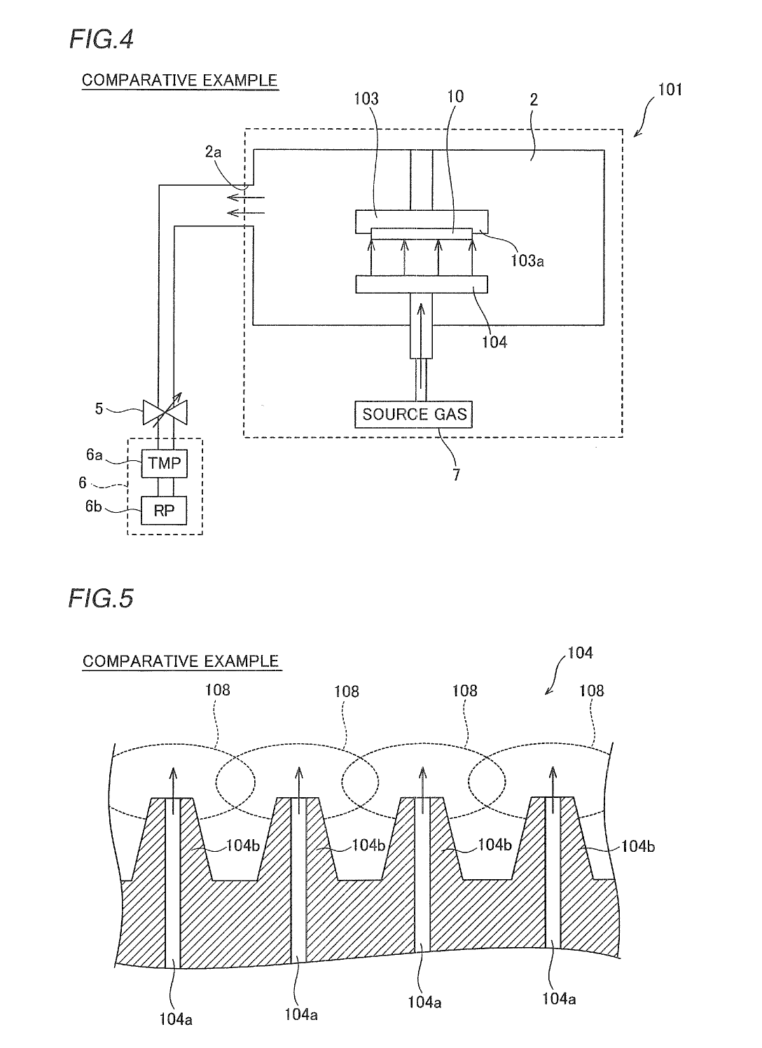

A plasma processing apparatus 101 according to comparative example is now described with reference to FIGS. 4 and 5.

In the plasma processing apparatus 101, an upper electrode 103 and a lower electrode 104 are set in a vacuum chamber 2 to be opposed to each other, as shown in FIG. 4. In the upper electrode 103, a substrate holding portion 103a capable of holding a substrate 10 is formed on a surface opposed to the lower electrode 104. Further, a plurality of gas supply ports 104a for supplying source gas are provided on a surface of the lower electrode 104 opposed to the upper electrode 103, as shown in FIG. 5. The gas supply ports 104a of the lower electrode 104 are connected to a source gas supply source 7. A structure for exhausting source gas is similar to that of the aforementioned embodiment.

According to comparative example, plasma is generated on the whole of the upper surface of the lower electrode 104 and the source gas is decomposed by the plasma, so that film formation is performed on the substrate 10. In the lower electrode 104, a plurality of projecting portions 104b are formed on a surface opposed to the upper electrode 103, as shown in FIG. 5. Thus, electric fields concentrate around forward end portions of the projecting portions 104b in the film formation, and it becomes possible to generate high-density plasma in plasma generation regions 108 centering on the projecting portions 104b. Consequently, it becomes possible to generate a larger number of film formation species, whereby it becomes possible to more enlarge a film formation rate. The projecting portions 104b are so formed that single through-holes constituting the gas supply ports 104a extend through centers thereof from base portions toward forward end portions thereby supplying the source gas in a direction directed from the forward end portions toward the upper electrode 103. In the plasma processing apparatus 101, therefore, the source gas is not sufficiently supplied between adjacent projecting portions 104b, and hence there is such a problem that qualities and thicknesses of films formed around the forward end portions of the projecting portions 104b and films formed between the adjacent projecting portions 104b become nonuniform.

According to this embodiment, on the other hand, the projecting portions 4b are so made of the conductive porous material that the source gas can be supplied not only from specific portions such as the forward end portions of the projecting portions 4b but also from sidewall portions of the projecting portions 4b. In other words, the source gas can be isotropically supplied from the projecting portions 4b according to this embodiment. Thus, plasma generation regions 8 centering on the projecting portions 4b and plasma generation regions 8 centering on the adjacent projecting portions 4b can be easily overlapped with each other. In other words, the plasma generation regions 8 can be arranged also on regions between the adjacent projecting portions 4b, whereby the plasma generation regions 8 can be arranged on the whole surface of the upper electrode 5. Film formation species can be generated on the whole surface of the lower electrode 3, whereby film qualities and film thicknesses can be effectively inhibited from becoming nonuniform.

According to this embodiment, as hereinabove described, the upper electrode 4 provided with the plurality of projecting portions 4b on the portion opposed to the lower electrode 3 is so provided that it becomes possible to concentrate the electric fields on the projecting portions 4b, whereby high-density plasma can be generated around the projecting portions 4b. Thus, decomposition efficiency of the source gas can be improved, whereby the film formation rate can be improved.

(First Modification)

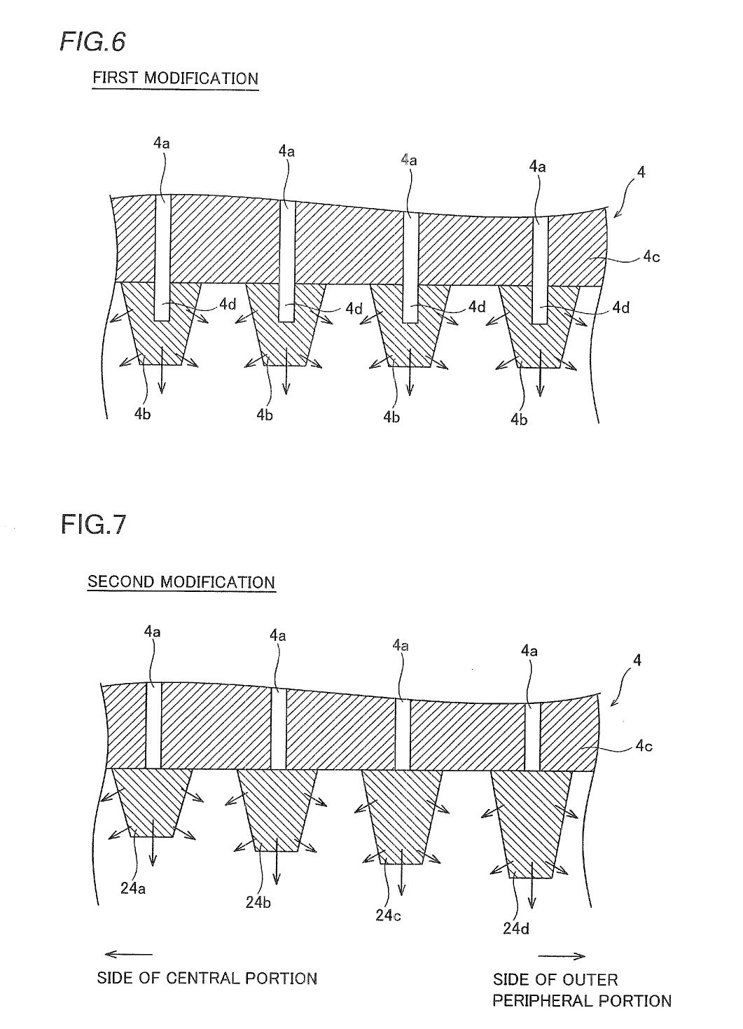

A first modification of the aforementioned embodiment is now described with reference to FIG. 6. In the first modification, the structure of projecting portions is different from that in the aforementioned embodiment.

According to the first modification, high porosity portions 4d are provided on projecting portions 4b to correspond to forward end portions of the projecting portions 4b, as shown in FIG. 6. The high porosity portions 4d are constituted of hollow recess portions linked (connected) to gas supply ports 4a in the projecting portions 4b. Thus, porosity of the high porosity portions 4d becomes higher than porosity of portions in the peripheries thereof. Conductance of source gas can be varied by adjusting the size of openings of the recess portions and the depth of the recess portions, whereby adjustment of a supply volume can be performed. The high porosity portions 4b may not be the hollow recess portions, but may be made of a conductive porous material having higher porosity than the peripheries of the projecting portions 4b. In this case, the conductance of the source gas can be varied by adjusting the volume, positions and porosity of the high porosity portions 4d, whereby adjustment of the supply volume can be performed.

The projecting portions 4b of the upper electrode 4 may simply be made of a conductive porous material capable of isotropically supplying the source gas from the forward end portions and the sidewall portions, and porous aluminum or porous titanium may be employed, in place of the porous carbon employed in this embodiment.

(Second Modification)

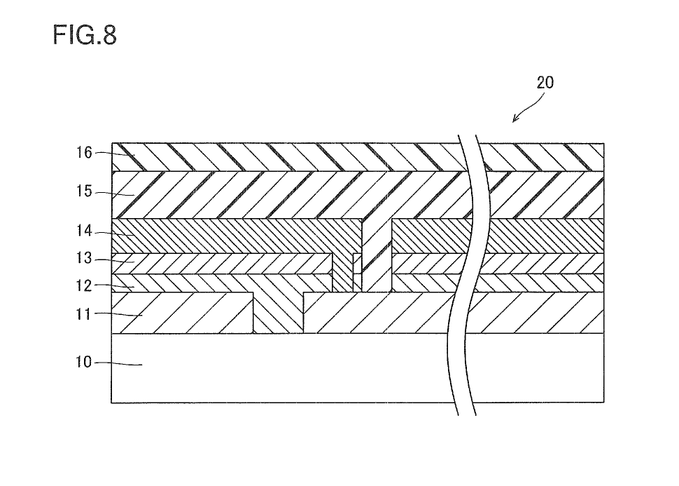

A second modification of the aforementioned embodiment is now described with reference to FIG. 7. In the second modification, the structure of an upper electrode is different from that in the aforementioned embodiment.

According to the second modification, an upper electrode 4 (shower plate 4c) is provided with a plurality of projecting portions 24a, 24b, 24c and 24d, as shown in FIG. 7. The projecting portion 24a, the projecting portion 24b, the projecting portion 24c and the projecting portion 24d are made of a conductive porous material such as porous carbon, similarly to the aforementioned embodiment. The projecting portion 24a, the projecting portion 24b, the projecting portion 24c and the projecting portion 24d are so formed that heights from base portions in contact with the shower plate 4c to forward end portions are larger in the projecting portions arranged on the side of the outer peripheral portion of the upper electrode 4 than in the projecting portions arranged on the side of a central portion of the upper electrode 4. More specifically, the projecting portions 24a, 24b, 24c and 24d are so formed that the projecting portion 24b is higher than the projecting portion 24a, the projecting portion 24c is higher than the projecting portion 24b and the projecting portion 24d is higher than the projecting portion 24c. Further, the projecting portions 24a (24b, 24c and 24d) are so formed that those positioned on concentric circles from the central portion of the upper electrode 4 (shower plate 4c) have heights of about the same degrees and the heights become higher (larger) stepwise from the central portion toward the outer peripheral portion of the upper electrode 4 (shower plate 4c).

Part of the source gas supplied to the central portion of the substrate 10 becomes a byproduct such as inert gas or flakes not contributing to the film formation. Due to this byproduct, there has arisen such a problem that the source gas is diluted on the outer peripheral portion of the substrate 10 and the film forming rate is reduced. This problem remarkably arises when increasing the size of the substrate or performing high-speed film formation by supplying the source gas in a large volume. In general, therefore, there has been required control of increasing a supply flow rate of the source gas on the outer peripheral portion as compared with the central portion of the substrate 10 in order to attain uniform film formation.

According to the second modification, the forward end portion of the projecting portion 24d arranged on the side of the outer peripheral portion more approaches a lower electrode 3 than the projecting portion 24a arranged on the side of the central portion of the substrate 10, whereby an electric field can be more concentrated on the outer peripheral portion as compared with the central portion. Consequently, decomposition efficiency of the source gas can be further improved and plasma of higher density can be generated on the outer peripheral portion of the substrate 10. Thus, it becomes possible to generate a larger number of film formation species, and it becomes possible to more enlarge the film formation rate. Consequently, the film formation rate on the outer peripheral portion of the substrate can be inhibited from lowering as compared with the substrate central portion by evacuation and film qualities and film thicknesses can be inhibited from becoming nonuniform, even if the source gas is supplied at a constant supply volume regardless of the positions of gas supply ports 4a of the shower plate 4c.

Control of adjusting the supply volume of the source gas to be larger on the outer peripheral portion than on the central portion of the substrate 10 may be combined with this structure of setting the heights from surfaces (base portions) in contact with the shower plate 4c to the forward end portions of the projecting portions 24a, 24b, 24c and 24d to be higher on the outer peripheral portion than on the central portion of the upper electrode 4. Thus, control can be more easily and finely performed, whereby the film qualities and the film thicknesses can be more inhibited from becoming nonuniform.

In the plasma processing apparatus 1, a shower plate having a plurality of projecting portions made of a conductive porous material may be employed as the upper electrode 4. In other words, the projecting portions 4b or the projecting portions 24a to 24d and the shower plate 4c may be integrated with each other.

The structure of a solar cell manufactured by employing the plasma processing apparatus 1 according to this embodiment is now described with reference to FIG. 8.

In a solar cell 20 manufactured by the plasma processing apparatus 1, a plurality of photovoltaic devices are arranged on a substrate 10, as shown in FIG. 8. In the plurality of photovoltaic devices, transparent conductive films 11, photoelectric conversion units 12 and 13 and rear electrodes 14 are successively stacked on the substrate 10.

The substrate 10, constituted of an optically transparent member of glass or the like, is a single substrate of the solar cell. The plurality of photovoltaic devices are formed on a rear surface side of this substrate 10 opposite to a light-incidence side.

The transparent conductive films 11 (substrate-side electrode) are oblongly formed on the substrate 10 in plan view. According to this embodiment, ZnO, having high light transmission properties, low resistance and plasticity, which is suitable due to a low cost is employed as the transparent conductive films 11.

The photoelectric conversion units 12 and 13 are oblongly formed on the transparent conductive films 11. The photoelectric conversion units 12 and 13 are made of an amorphous silicon semiconductor and a microcrystalline silicon semiconductor respectively. In this specification, it is assumed that the term “microcrystalline” denotes not only a complete crystal structure, but also a state partially including an amorphous state.

The rear electrodes 14 (rear-side electrodes) are constituted of conductive members of Ag or the like, and oblongly formed on the photoelectric conversion units 12 and 13. Layers made of a transparent conductive material may be interposed between the rear electrodes 14 and the photoelectric conversion units 13.

While the photoelectric conversion units 12 and 13 in which the amorphous silicon semiconductor and the microcrystalline silicon semiconductor are successively stacked have been employed in this embodiment, similar effects can be attained also when employing a single layer of a microcrystalline or amorphous photoelectric conversion unit or a laminate of at least three layers. Further, a structure of providing an intermediate layer made of ZnO, SnO₂, SiO₂ or MgZnO between a first photovoltaic device and a second photovoltaic device for improving optical characteristics may be employed. In addition, the transparent conductive films 11 may be constituted of laminates of one type or a plurality of types selected from metal oxides of In₂O₃, SnO₂, TiO₂ and Zn₂SnO₄, in addition to ZnO employed in this embodiment.

A method of manufacturing the aforementioned solar cell by employing the plasma processing apparatus 1 is now described.

First, a ZnO electrode 11 of 600 nm in thickness is formed on the glass substrate 10 of 4 mm in thickness by sputtering.

Thereafter a YAG laser is applied from the side of the glass substrate 10 closer to the ZnO electrode 11, to oblongly pattern the ZnO electrode 11. An Nd:YAG laser having a wavelength of about 1.06 μm, energy density of 13 J/cm³ and a pulse frequency of 3 kHz is used for this laser separation processing.

Then, the photoelectric conversion units 12 and 13 are formed by the plasma processing apparatus 1.

More specifically, the substrate 10 is fixed to the substrate holding portion 3a formed on the surface of the lower electrode 3 of the plasma processing apparatus 1 opposed to the upper electrode 4, and the vacuum chamber 2 is thereafter evacuated by the evacuation system 6.

Then, the source gas is isotropically supplied to the space between the upper electrode 4 and the lower electrode 3 from the projecting portions 4b of the upper electrode 4 connected to the source gas supply source 7 (see FIG. 1), as shown in FIG. 2. In other words, the source gas is supplied not only from the forward end portions but also from the sidewall portions of the projecting portions 4b. Thereafter high-frequency power is supplied to the upper electrode 4, thereby isotropically generating plasma in the vicinity of the forward end portions of the projecting portions 4b and in regions between the adjacent projecting portions 4b while centering on the projecting portions 4b of the upper electrode 4. Thus, the source gas is decomposed by the plasma and film formation species are generated. The film formation species generated by decomposition of the source gas with the plasma are deposited on the substrate 10, whereby a prescribed film (not shown) is formed on the substrate 10.

Then, the photoelectric conversion units 12 are formed by forming p-type amorphous silicon semiconductor layers of 10 nm in thickness by employing mixed gas of SiH₄, CH₄, H₂ and B₂H₆ as source gas, forming i-type amorphous silicon semiconductor layers of 300 nm in thickness by employing mixed gas of SiH₄ and H₂ as source gas and forming n-type amorphous silicon semiconductor layers of 20 nm in thickness by employing mixed gas of SiH₄, H₂ and PH₄ as source gas in the plasma processing apparatus 1 and successively stacking the layers. Further, the photoelectric conversion units 13 are formed by forming p-type microcrystalline silicon semiconductor layers of 10 nm in thickness by employing mixed gas of SiH₄, H₂ and B₂H₆ as source gas, forming i-type microcrystalline silicon semiconductor layers of 2000 nm in thickness by employing mixed gas of SiH₄ and H₂ as source gas and forming n-type microcrystalline silicon semiconductor layers of 20 nm in thickness by employing mixed gas of SiH₄, H₂ and PH₄ as source gas in the plasma processing apparatus 1 and successively stacking the same. Table 1 shows the details of various conditions for the plasma processing apparatus.

TABLE 1

| | | Substrate | | | | |
|---|---|---|---|---|---|---|
| | | Tempera- | Gas Flow | Reaction | RF | Film |
| | | ture | Rate | Pressure | Power | Pressure |
| | Layer | (° C.) | (sccm) | (Pa) | (W) | (nm) |
| Amor- | p | 180 | SiH₄: 300 | 106 | 10 | 10 |
| phous | Layer | | CH₄: 300 | | | |
| Si | | | H₂: 2000 | | | |
| Film | | | B₂H₆: 3 | | | |
| | i | 200 | SiH₄: 300 | 106 | 20 | 300 |
| | Layer | | H₂: 2000 | | | |
| | n | 180 | SiH₄: 300 | 133 | 20 | 20 |
| | Layer | | H₂: 2000 | | | |
| | | | PH₄: 5 | | | |
| Micro- | p | 180 | SiH₄: 10 | 106 | 10 | 10 |
| crystalline | Layer | | H₂: 2000 | | | |
| Si Film | | | B₂H₆: 3 | | | |
| | i | 200 | SiH₄: 100 | 133 | 20 | 2000 |
| | Layer | | H₂: 2000 | | | |
| | n | 200 | SiH₄: 10 | 133 | 20 | 20 |
| | Layer | | H₂: 2000 | | | |
| | | | PH₄: 5 | | | |

Then, the stacked photoelectric conversion units 12 and 13 are oblongly patterned by applying a YAG laser to a side of a patterned position of the ZnO electrode 11 from the side of the ZnO electrode. An Nd:YAG laser having energy density of 0.7 J/cm³ and a pulse frequency of 3 kHz is used for this laser separation processing.

Then, Ag electrodes 14 of 200 nm in thickness are formed on the photoelectric conversion units 13 by sputtering. The Ag electrodes 14 are formed also on regions where the photoelectric conversion units 12 and 13 have been removed by patterning.

Then, a YAG laser is applied to portions on sides of patterned positions of the photoelectric conversion units 12 and 13, thereby separating the Ag electrodes 14 and the photoelectric conversion units 12 and 13 from each other and oblongly patterning the same. An Nd:YAG laser having energy density of 0.7 J/cm³ and a pulse frequency of 4 kHz is used for this laser separation processing.

Thus, the solar cell 20 in which the plurality of photovoltaic devices are serially connected on the glass substrate 10 is formed. A filler 15 made of EVA (ethylene vinyl acetate) or the like and a back sheet 16 made of PET/Al foil/PET or the like are provided on the rear electrodes 14 of this solar cell 20, to form a solar cell module.

In the inventive method of manufacturing a solar cell according to the present invention, film qualities and film thicknesses can be inhibited from becoming nonuniform even if a film formation rate is enlarged, whereby desired excellent films can be formed. Consequently, reduction of conversion efficiency resulting from nonuniformity of the film qualities and the film thicknesses can be prevented, whereby higher power can be extracted. In other words, improvement of the film formation rate and prevention of reduction of the conversion efficiency of the solar cell can be rendered compatible in the method of manufacturing a solar cell according to the present invention.

While the example of forming all of the photoelectric conversion units 12 and 13 by the plasma processing apparatus 1 has been shown in the aforementioned embodiment, the present invention is not restricted to this. According to the present invention, at least parts of the photoelectric conversion units 12 and 13 may simply be formed by the plasma processing apparatus 1.

1. A method of manufacturing a solar cell, comprising the steps of:
forming a substrate-side electrode (11) on a substrate (10);
forming at least part of a photoelectric conversion unit (12, 13) on said substrate-side electrode by supplying source gas from projecting portions of a plasma processing apparatus (1) including a first electrode (4) having said projecting portions (4b, 24a, 24b, 24c, 24d), made of a conductive porous material, provided to cover gas supply ports (4a); and
forming a rear-side electrode (14) on said photoelectric conversion unit.

2. The method of manufacturing a solar cell according to claim 1, wherein
the step of forming said photoelectric conversion unit includes a step of forming said photoelectric conversion unit on said substrate-side electrode by isotropically supplying the source gas from forward end portions and sidewall portions of said projecting portions and isotropically generating plasma from said projecting portions.

3. The method of manufacturing a solar cell according to claim 2, wherein
said plasma processing apparatus includes a second electrode (3), holding said substrate, opposed to said first electrode, and
the step of forming said photoelectric conversion unit includes a step of forming at least part of said photoelectric conversion unit on said substrate-side electrode by supplying the source gas in a direction directed from the forward end portions of said projecting portions toward said second electrode and a direction directed from the sidewall portions toward adjacent said projecting portions and isotropically generating the plasma from said projecting portions.

4. The method of manufacturing a solar cell according to claim 1, wherein
said photoelectric conversion unit includes a plurality of photoelectric conversion units in which a microcrystalline photoelectric conversion unit is included.

5. The method of manufacturing a solar cell according to claim 4, wherein
said photoelectric conversion unit includes an amorphous photoelectric conversion unit, in addition to said microcrystalline photoelectric conversion unit.

6. The method of manufacturing a solar cell according to claim 1, wherein
said photoelectric conversion unit is a thin-film photoelectric conversion unit having a photoelectric conversion thin film.

7. The method of manufacturing a solar cell according to claim 1, wherein
the step of forming said photoelectric conversion unit includes a step of forming at least part of the photoelectric conversion unit on said substrate-side electrode by supplying the source gas from said projecting portions in a state adjusting the volume of gas supplied to said projecting portion, made of the conductive porous material, arranged on an outer peripheral portion of said first electrode to be larger than the volume of the gas supplied to said projecting portion, made of the conductive porous material, arranged on a central portion.

8. The method of manufacturing a solar cell according to claim 1, wherein
said projecting portions are made of porous carbon.

9. A plasma processing apparatus comprising:
a first electrode (4) arranged in a processing chamber (2);
a second electrode (3), opposed to said first electrode, capable of holding a substrate (10); and
a gas supply source (7) supplying gas into said processing chamber, wherein
said first electrode has a shower plate (4c) formed by a conductive substrate having gas supply ports (4a) and projecting portions (4b, 24a, 24b, 24c, 24d), made of a conductive porous material, provided on a surface of said shower plate opposed to said second electrode to cover said gas supply ports, and is formed to supply source gas from said projecting portions.

10. The plasma processing apparatus according to claim 9, wherein
said projecting portions are formed to isotropically supply the source gas from forward end portions and sidewall portions of said projecting portions and to isotropically generate plasma.

11. The plasma processing apparatus according to claim 10, wherein
said projecting portions are formed to supply the source gas in a direction directed from the forward end portions of said projecting portions toward said second electrode and a direction directed from the sidewall portions toward adjacent said projecting portions and to isotropically generate the plasma.

12. The plasma processing apparatus according to claim 9, wherein
the heights of said projecting portions from base portions in contact with said shower plate to forward end portions are larger in projecting portions arranged on an outer peripheral portion of said shower plate than in projecting portions arranged on a central portion of said shower plate.

13. The plasma processing apparatus according to claim 12, so formed that the heights of said plurality of projecting portions from base portions in contact with said shower plate to forward end portions enlarge stepwise from the projecting portions arranged on the central portion of said shower plate toward the projecting portions arranged on the outer peripheral portion of said shower plate.

14. The plasma processing apparatus according to claim 9, wherein
said projecting portions have regions (4d) having high porosity and regions having low porosity.

15. The plasma processing apparatus according to claim 14, wherein
the regions of said projecting portions having high porosity are connected to said gas supply ports.

16. The plasma processing apparatus according to claim 15, wherein
the regions of said projecting portions having high porosity consist of hollow recess portions formed to be connected to said gas supply ports.

17. The plasma processing apparatus according to claim 9, wherein
said shower plate and said projecting portions are integrally made of the conductive porous material.

18. The plasma processing apparatus according to claim 9, so formed that the width of said projecting portions in a direction along the surface of said shower plate is gradually reduced as directed toward forward end portions of said projecting portions.

19. The plasma processing apparatus according to claim 9, wherein
a plurality of the projecting portions made of said conductive porous material are concentrically provided on the surface of said shower plate.

20. The plasma processing apparatus according to claim 9, wherein
said projecting portions are made of porous carbon.
